(19) United States
(12) Patent Application Publication
(10) Pub. No.: US 2026/0271378 A1
(43) Pub. Date: Sep. 10, 2026

(54) SEMICONDUCTOR DEVICE

(71) Applicant: DENSO CORPORATION, Kariya-city (JP)

(72) Inventor: Shuji YONEDA, Kariya-city (JP)

(21) Appl. No.: 19/661,063

(22) Filed: Apr. 28, 2026

Related U.S. Application Data
(63) Continuation of application No. PCT/JP2024/040863, filed on Nov. 18, 2024.

(30) Foreign Application Priority Data
Nov. 20, 2023 (JP) 2023-196771

(51) Int. Cl. H10D 84/00; H10D 12/00; H10D 62/10; H10D 62/60

(52) U.S. Cl. CPC H10D 84/161; H10D 12/481; H10D 62/124; H10D 62/60; H10D 62/102

(57) ABSTRACT

A semiconductor device includes a main element and a sense element formed in a semiconductor substrate. The main element includes a drift layer, a base layer, an emitter region, a gate insulating film, a gate electrode layer, and a collector layer. The sense element includes the drift layer, the collector layer, and a well layer. The emitter region and the base layer are electrically connected to an emitter electrode. The collector layer is electrically connected to a collector electrode. The well layer is electrically connected to a sense electrode. When a predetermined voltage is applied to the gate electrode layer, first carriers are supplied from the emitter electrode to the drift layer, second carriers are supplied from the collector electrode to the drift layer, and a portion of the second carriers supplied to the drift layer flows into the well layer.

### CROSS REFERENCE TO RELATED APPLICATIONS

The present application is a continuation application of International Patent Application No. PCT/JP2024/040863 filed on November 18, 2024, which designated the U.S. and claims the benefit of priority from Japanese Patent Application No. 2023-196771 filed on November 20, 2023. The entire disclosures of all of the above applications are incorporated herein by reference.

### TECHNICAL FIELD

The present disclosure relates to a semiconductor device.

### BACKGROUND

Conventionally, semiconductor devices having a main cell region in which a main element is formed and a sense cell region in which a sense element is formed have been proposed. Specifically, in the semiconductor devices described above, the main element and the sense element are configured by forming insulated gate bipolar transistor (IGBT) elements of the same structure, each having a gate structure, an emitter region, and other components. In addition, the main element and the sense element (that is, the main cell region and the sense cell region) are formed with a predetermined area ratio. The semiconductor devices described above may be provided with a temperature detection unit that detects a temperature of a semiconductor substrate on which the main element and the sense element are formed.

### SUMMARY

A semiconductor device according to an aspect of the present disclosure includes a semiconductor substrate, an emitter electrode, a collector electrode, and a sense electrode. The semiconductor substrate has a main cell region in which a main element is disposed and a sense cell region in which a sense element is disposed. The semiconductor substrate includes a drift layer of a first conductivity type disposed in the main cell region and the sense cell region, a base layer of a second conductivity type disposed on the drift layer in the main cell region, an emitter region of the first conductivity type disposed in a surface portion of the base layer and having a higher impurity concentration than the drift layer, a gate insulating film disposed on a surface of the base layer between the emitter region and the drift layer, a gate electrode layer disposed on the gate insulating film, a collector layer of the second conductivity type disposed on a side of the drift layer opposite to the base layer, and a well layer of the second conductivity type disposed on the drift layer in the sense cell region. The emitter electrode is electrically connected to the emitter region and the base layer. The collector electrode is electrically connected to the collector layer. The sense electrode is electrically connected to the well layer. The main element includes the drift layer, the base layer, the emitter region, the gate insulating film, the gate electrode layer, and the collector layer. The sense element includes the drift layer, the collector layer, and the well layer. The sense element is configured to be connected to a detection unit, and a main current flowing through the main element is detected based on a detection result of the detection unit. When a predetermined voltage is applied to the gate electrode layer, first carriers are supplied from the emitter electrode to the drift layer, second carriers are supplied from the collector electrode to the drift layer, and a portion of the second carriers supplied to the drift layer may flow into the well layer. The well layer may be spaced apart from the base layer in the main cell region, and the well layer may have a distance ratio, which is a ratio of a distance between the well layer and the base layer to a thickness of the semiconductor substrate, of 4 or less.

### BRIEF DESCRIPTION OF DRAWINGS

Objects, features and advantages of the present disclosure will become apparent from the following detailed description made with reference to the accompanying drawings. In the drawings:

FIG. 1 is a cross-sectional view of a semiconductor device according to a first embodiment;

FIG. 2 is a diagram showing a hole current when the semiconductor device is in an ON state;

FIG. 3 is a circuit diagram when detecting a current flowing through a main element;

FIG. 4 is a diagram showing a semiconductor device used in a simulation;

FIG. 5A is a diagram showing a hole current density at 25 °C;

FIG. 5B is a diagram showing a hole current density at 90 °C;

FIG. 5C is a diagram showing a hole current density at 150 °C;

FIG. 6 is a diagram showing a relationship between a collector current and a detection voltage of the semiconductor device in the first embodiment;

FIG. 7 is a diagram showing a relationship between a collector current and a detection voltage of the semiconductor device in a comparative example;

FIG. 8 is a diagram showing a relationship between temperature and a temperature characteristic ratio;

FIG. 9A is a diagram showing an electron current density at 25 °C;

FIG. 9B is a diagram showing an electron current density at 90 °C;

FIG. 9C is a diagram showing an electron current density at 150 °C;

FIG. 10 is a diagram showing a relationship between a distance ratio and a detection voltage;

FIG. 11 is a cross-sectional view of a semiconductor device according to a second embodiment; and

FIG. 12 is a cross-sectional view of a semiconductor device according to a modification of the second embodiment.

### DETAILED DESCRIPTION

In a semiconductor device having a main cell region in which a main element is formed and a sense cell region in which a sense element is formed, and equipped with a temperature detection unit that detects the temperature of a semiconductor substrate on which the main element and the sense element are formed, a current flowing through the main element may be detected as follows. In the semiconductor device, a detection resistor is connected in series with the sense element. When detecting the current flowing through the main element, a control unit, which performs predetermined processing, uses a voltage across the detection resistor as a detection voltage and detects the current flowing through the main element based on the detection voltage.

More specifically, when the main element and the sense element have the same structure, the current flowing through the main element and the current flowing through the sense element depend on the area ratio between the main element and the sense element. Therefore, the main current flowing through the main element is derived from the sense current flowing through the sense element (that is, the detection voltage) and the area ratio between the main element and the sense element. At this time, the control unit detects the current flowing through the main element while performing correction using the temperature detected by the temperature detection unit.

However, in a configuration that includes a temperature detection unit, the structure may become more complex. The inventors have been investigating a semiconductor device that can reduce the effects of temperature without including a temperature detection unit and without performing temperature correction.

A semiconductor device according to an aspect of the present disclosure includes a semiconductor substrate, an emitter electrode, a collector electrode, and a sense electrode. The semiconductor substrate has a main cell region in which a main element is disposed and a sense cell region in which a sense element is disposed. The semiconductor substrate includes a drift layer of a first conductivity type disposed in the main cell region and the sense cell region, a base layer of a second conductivity type disposed on the drift layer in the main cell region, an emitter region of the first conductivity type disposed in a surface portion of the base layer and having a higher impurity concentration than the drift layer, a gate insulating film disposed on a surface of the base layer between the emitter region and the drift layer, a gate electrode layer disposed on the gate insulating film, a collector layer of the second conductivity type disposed on a side of the drift layer opposite to the base layer, and a well layer of the second conductivity type disposed on the drift layer in the sense cell region. The emitter electrode is electrically connected to the emitter region and the base layer. The collector electrode is electrically connected to the collector layer. The sense electrode is electrically connected to the well layer. The main element includes the drift layer, the base layer, the emitter region, the gate insulating film, the gate electrode layer, and the collector layer. The sense element includes the drift layer, the collector layer, and the well layer. The sense element is configured to be connected to a detection unit, and a main current flowing through the main element is detected based on a detection result of the detection unit. When a predetermined voltage is applied to the gate electrode layer, first carriers are supplied from the emitter electrode to the drift layer, second carriers are supplied from the collector electrode to the drift layer, and a portion of the second carriers supplied to the drift layer may flow into the well layer.

According to this configuration, in the sense cell region, the well layer is disposed on the drift layer, and when the main cell region is in an ON state, a portion of the second carriers flows into the well layer. In this case, the detection result of the detection unit connected to the sense element is based on the second carriers, and the detection result is not affected by temperature. Therefore, according to the semiconductor device described above, when detecting the main current based on the detection result of the detection unit connected to the sense element, the main current can be detected with reduced influence of temperature even without performing temperature correction.

The following describes embodiments of the present disclosure with reference to the drawings. In the following embodiments, the same or equivalent parts are denoted by the same reference numerals for description.

### First embodiment

A first embodiment will be described with reference to the drawings. A semiconductor device of the present embodiment is preferably mounted on a vehicle such as an automobile and applied as a device for driving various electronic devices for the vehicle.

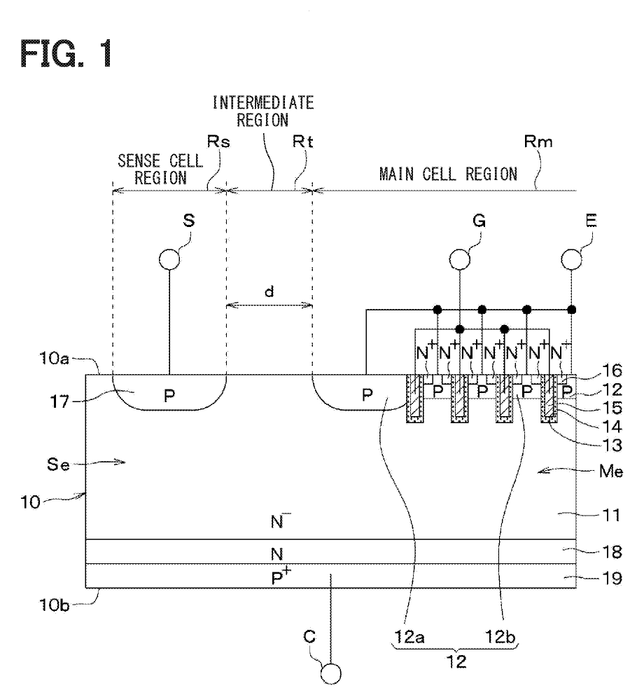

As shown in FIG. 1, the semiconductor device of the present embodiment has a main cell region Rm in which a main element Me is formed, and a sense cell region Rs in which a sense element Se is formed. The main cell region Rm and the sense cell region Rs are formed with a predetermined area ratio (for example, several thousand to one).

The semiconductor device is constructed using a semiconductor substrate 10, and the semiconductor substrate 10 has a drift layer 11 of N⁻-type. In the present embodiment, the semiconductor substrate 10 has a thickness of approximately 130 μm. In the main cell region Rm, a base layer 12 of P-type with a relatively low impurity concentration is disposed on the drift layer 11. In the present embodiment, the base layer 12 includes an outer edge base layer 12a located adjacent to the sense cell region Rs and an inner edge base layer 12b located further inward from the outer edge base layer 12a. The outer edge base layer 12a is formed deeper than the inner edge base layer 12b so as to suppress the occurrence of electric field concentration at an outer edge portion in the main cell region Rm. Hereinafter, in the semiconductor substrate 10, a surface adjacent to the base layer 12 is referred to as a first surface 10a of the semiconductor substrate 10, and a surface located opposite to the first surface 10a is referred to as a second surface 10b.

In the semiconductor substrate 10, a plurality of trenches 13 are formed in the main cell region Rm so as to penetrate through the base layer 12 from the first surface 10a into the drift layer 11. The base layer 12 of the main cell region Rm is separated into a plurality of sections by the trenches 13. The trenches13 extend in such a manner that their longitudinal direction is aligned with one direction in the plane of the first surface 10a of the semiconductor substrate 10 (that is, the depth direction in the drawing of FIG. 1). The trenches 13 have a stripe shape and are arranged at equal intervals. A portion of the base layer 12 located closer to the sense cell region Rs relative to the trench 13 positioned at an end in a transverse direction that intersects the one direction is defined as the outer edge base layer 12a. It should be noted that the transverse direction may also be referred to as the arrangement direction of the trenches 13.

Each of the trenches 13 is filled with a gate insulating film 14 and a gate electrode layer 15. The gate insulating film 14 is formed so as to cover a wall surface of each of the trenches 13. The gate electrode layer 15 is formed from polysilicon or the like and is disposed on the gate insulating film 14. Accordingly, a trench gate structure is formed. In the present embodiment, a portion of the wall surface of each of the trenches 13 for exposing the base layer 12 corresponds to a surface of the base layer 12 arranged between an emitter region 16 and the drift layer 11.

In the main cell region Rm, the emitter region 16 of N⁺-type is formed in a surface portion of the base layer 12. Specifically, the emitter region 16 is formed with a higher impurity concentration than the drift layer 11 and is formed along the longitudinal direction of the trenches 13. Although not specifically shown in FIG. 1, a contact region of P⁺-type with a higher impurity concentration than the base layer 12 may be formed at a portion in the surface portion of the base layer 12 located on the opposite side of the emitter region 16 from each of the trenches 13.

In the sense cell region Rs, a well layer 17 of P-type is formed on the drift layer 11. In the present embodiment, the well layer 17 is spaced apart from the base layer 12 by a distance d. Therefore, in the present embodiment, the drift layer 11 is arranged between the well layer 17 and the base layer 12. In other words, in the semiconductor device of the present embodiment, an intermediate region Rt, in which neither the base layer 12 nor the well layer 17 is formed, is arranged between the main cell region Rm and the sense cell region Rs.

It should be noted that in the present embodiment, the well layer 17 has the same impurity concentration as the outer edge base layer 12a in the main cell region Rm, and is formed to the same depth as the outer edge base layer 12a. Therefore, the well layer 17 is formed in the same process as the process for forming the outer edge base layer 12a.

Then, in the main cell region Rm, the base layer 12 and the emitter region 16 are connected to an emitter electrode E, and the gate electrode layer 15 is connected to a gate electrode G. In the sense cell region Rs, the well layer 17 is connected to the sense electrode S.

In the main cell region Rm and the sense cell region Rs, a field stop layer of N-type (hereinafter simply referred to as the FS layer 18) is formed on a side of the drift layer 11 opposite to the base layer 12, that is, adjacent to the second surface 10b of the semiconductor substrate 10. The FS layer 18 is not necessarily essential, but it is provided to improve breakdown voltage and steady-state loss performance by preventing the expansion of the depletion layer, as well as to control the amount of holes injected from the side of the second surface 10b of the semiconductor substrate 10.

On a side of the FS layer 18 opposite to the drift layer 11, a collector layer 19 of P-type is formed. Then, the collector layer 19 is connected to a collector electrode C.

The above describes the configuration of the semiconductor device in the present embodiment. In the present embodiment, N-type, N⁻-type, and N⁺-type correspond to a first conductivity type, and P-type and P⁺-type correspond to a second conductivity type. In the semiconductor device, as described above, the semiconductor substrate 10 is configured to include the collector layer 19, the FS layer 18, the drift layer 11, the base layer 12, the emitter region 16, and the like. In addition, although details are omitted above, the semiconductor device is provided with a termination structure such as a guard ring formed so as to surround the main cell region Rm and the sense cell region Rs.

Next, a more detailed configuration will be described while explaining the operation of the semiconductor device and the main current (that is, a collector current IC) that flows through the main cell region Rm.

In the semiconductor device of the present embodiment, when a voltage lower than that of the collector electrode C is applied to the emitter electrode E, and a voltage equal to or higher than the threshold voltage of the insulated gate structure is applied to the gate electrode layer 15, an inversion layer of N-type (that is, channel) is formed in the portion of the base layer 12 that is in contact with the trenches 13. Then, in the main cell region Rm, electrons are supplied from the emitter region 16 to the drift layer 11 via the inversion layer, while holes are supplied from the collector layer 19 to the drift layer 11. Due to conductivity modulation, the resistance value of the drift layer 11 decreases, resulting in an on-state in which the collector current IC flows. In the present embodiment, electrons correspond to first carriers, while holes correspond to second carriers.

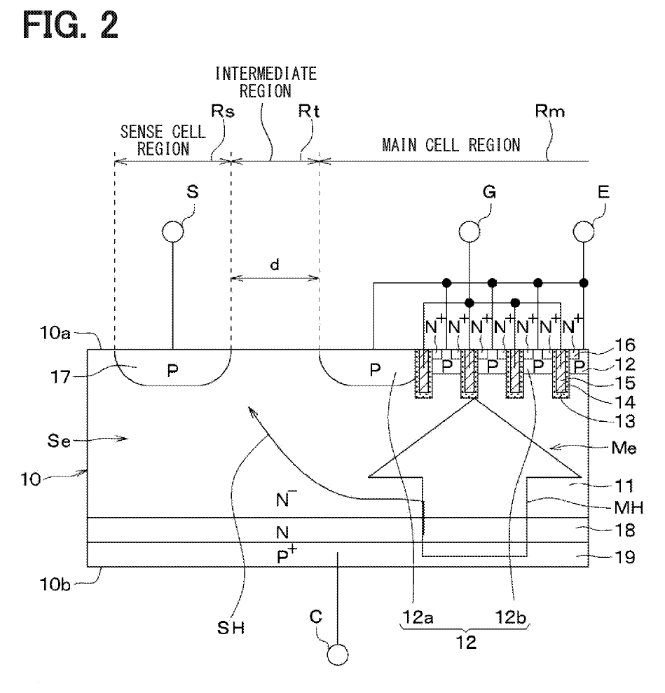

Here, in terms of energy bands, the energy for holes supplied to the drift layer 11 is lower in layers of P-type than in layers of N-type. Therefore, a portion of the holes supplied to the drift layer 11 becomes a hole current that flows into the layers of P-type. In the present embodiment, the base layer 12 of P-type is formed in the main cell region Rm, and the well layer 17 of P-type is formed in the sense cell region Rs. Therefore, as shown in FIG. 2, the hole current is divided into a main hole current MH that flows into the base layer 12 in the main cell region Rm, and a sense hole current SH that flows into the well layer 17 in the sense cell region Rs. The main hole current MH and the sense hole current SH flow at a predetermined ratio according to factors such as the impurity concentrations of the drift layer 11, the base layer 12, and the well layer 17.

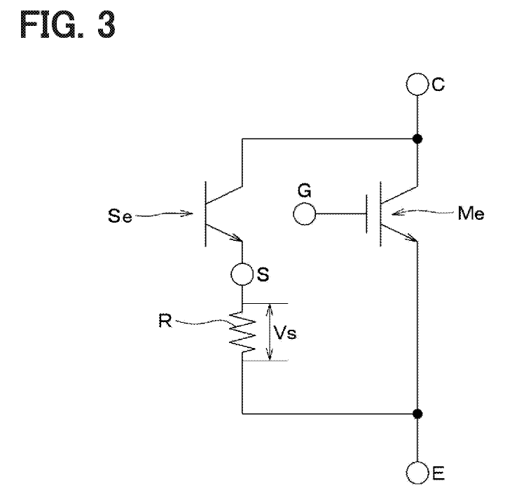

Then, the main current (that is, the collector current IC) in the main cell region Rm of the semiconductor device according to the present embodiment is detected using a circuit configuration as shown in FIG. 3. Specifically, in this circuit configuration, a detection resistor R, which is composed of a shunt resistor and serves as a detection unit, is provided between the sense electrode S of the sense element Se and the emitter electrode E of the main element Me.

Then, the main current flowing through the main element Me is detected based on a detection voltage Vs, which is a voltage across the detection resistor R, by a control unit or the like (not shown). More specifically, first, the sense current flowing through the sense element Se is detected from the detection voltage Vs. It should be noted that the sense current in the present embodiment is the sense hole current SH. In the present embodiment, the detection voltage Vs corresponds to a detection result.

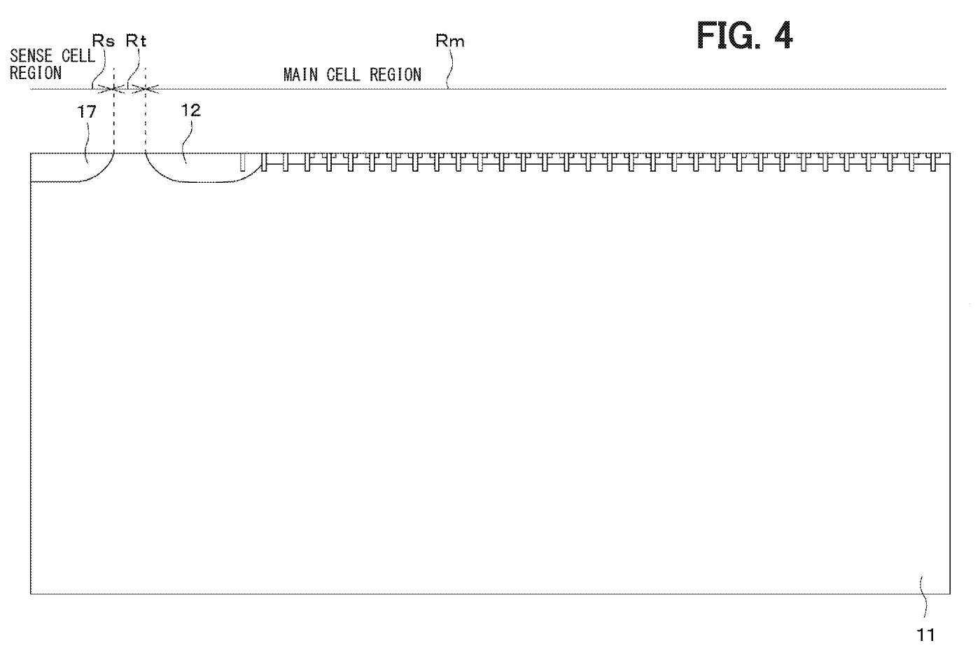

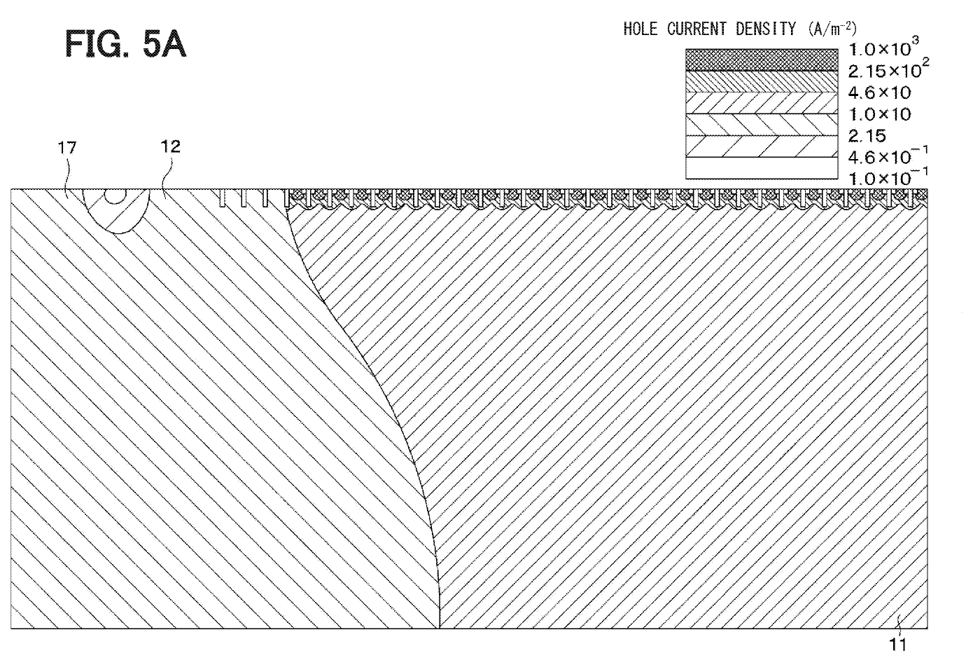

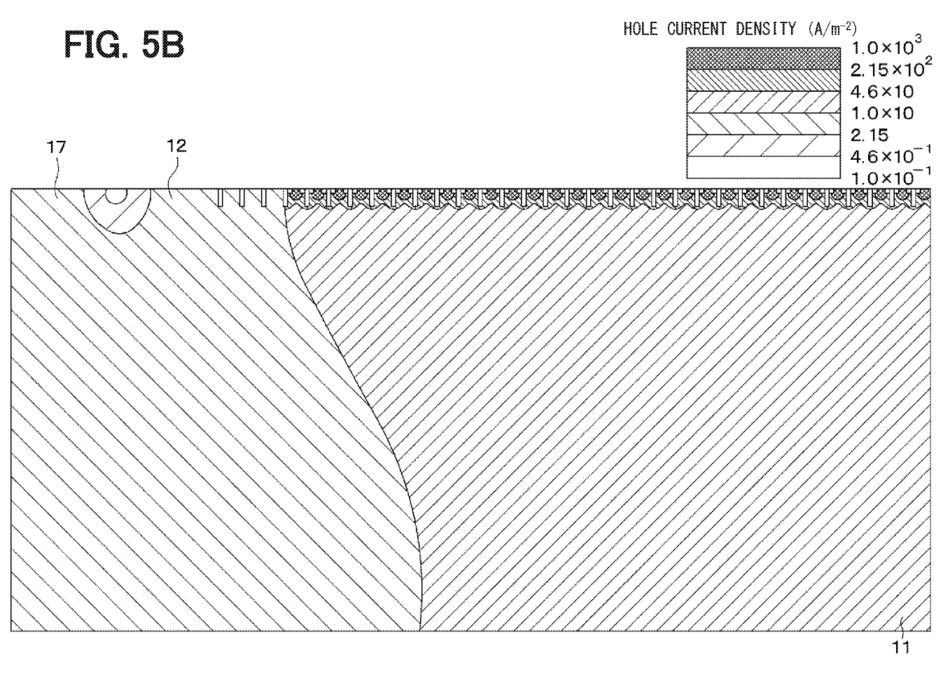

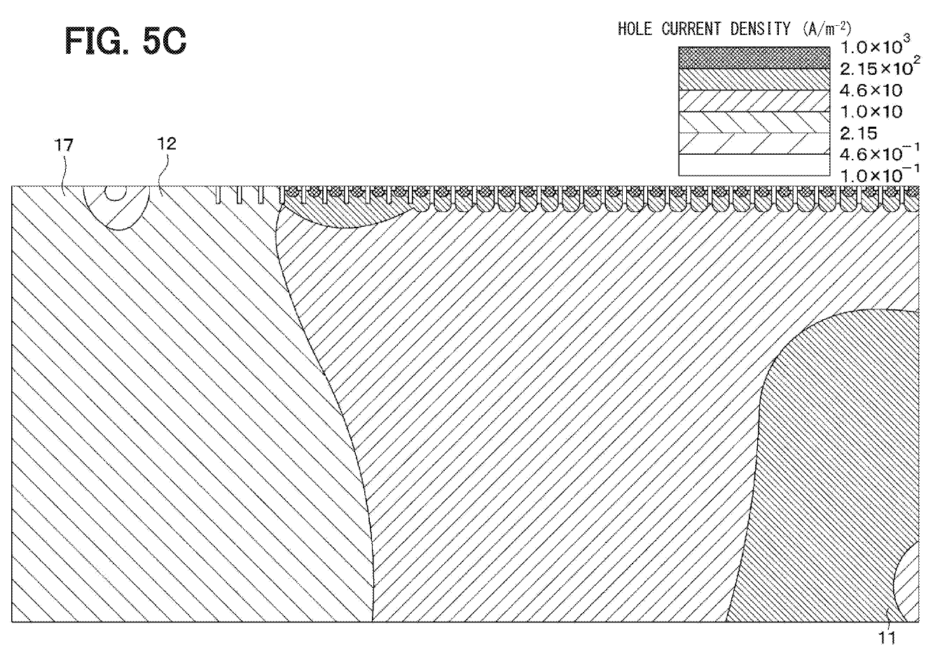

Here, the present inventors conducted extensive studies on a hole current density for a model shown in FIG. 4, and obtained the results shown in FIGS. 5A to 5C. FIG. 5A is a diagram showing a hole current density at 25 °C. FIG. 5B is a diagram showing a hole current density at 90 °C. FIG. 5C is a diagram showing a hole current density at 150 °C. As shown in FIGS. 5A to 5C, it is confirmed that the hole current density hardly changes even when the temperature varies. It should be noted that the model shown in FIG. 4 sets the area ratio of the main cell region Rm to the sense cell region Rs to 30:1.

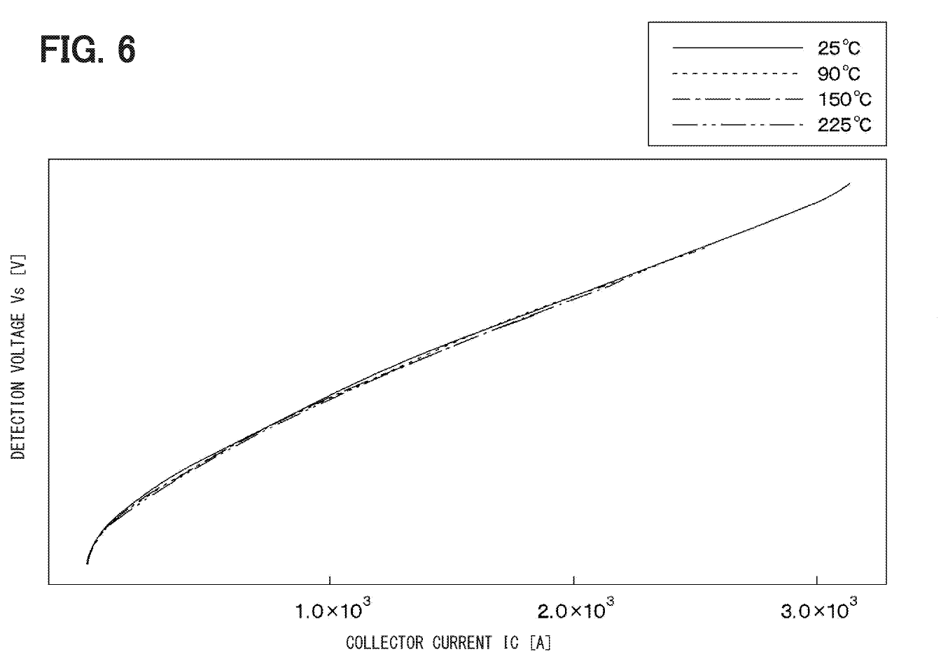

The present inventors then obtained the results shown in FIG. 6 regarding the relationship between the collector current IC (that is, the main current) flowing through the main cell region Rm and the detection voltage Vs across the detection resistor R when the temperature is varied. As shown in FIG. 6, it is confirmed that the detection voltage Vs is almost independent of temperature.

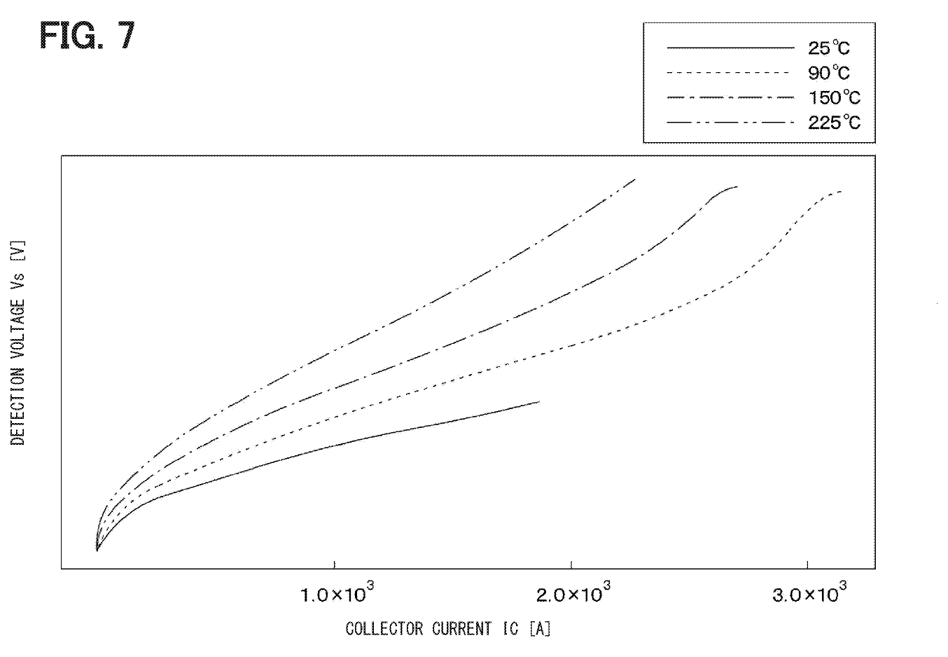

In contrast, a semiconductor device in which the sense cell region Rs has the same configuration as the main cell region Rm is taken as a comparative example. Then, it is confirmed, as shown in FIG. 7, that the detection voltage Vs in the semiconductor device of the comparative example varies significantly depending on temperature.

It should be noted that the detection voltages Vs shown in FIGS. 6 and 7 are results obtained when the resistance value of the detection resistor R is set to 1 Ω. Furthermore, FIGS. 6 and 7 show results obtained when the distance d is set to 13 μm. In other words, setting the distance d to 13 μm means that the distance d is set to approximately 10% of the thickness of the semiconductor substrate 10.

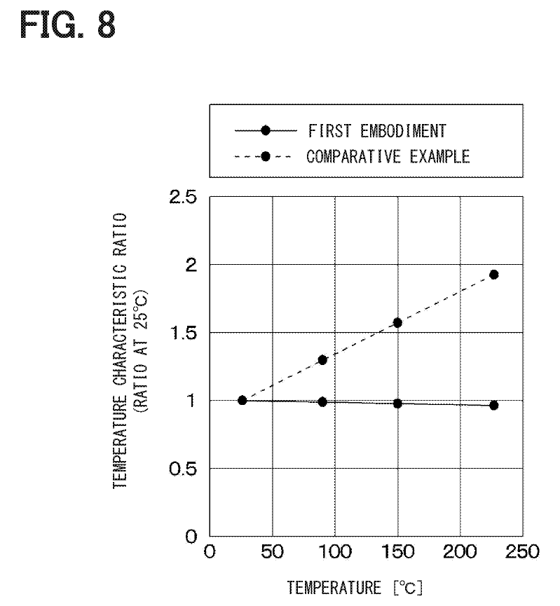

Then, when the detection voltage Vs at 25 °C is taken as the reference for the temperature characteristic ratio (that is, a temperature characteristic ratio of 1), it is confirmed, as shown in FIG. 8, that in the semiconductor device of the present embodiment, the temperature characteristic ratio remains almost unchanged even if the temperature varies. In contrast, it is confirmed that in the semiconductor device of the comparative example, the temperature characteristic ratio increases as the temperature rises. It should be noted that the temperature characteristic ratio in FIG. 8 is the result obtained when the resistance value of the detection resistor R is set to 1 Ω and the collector current IC is set to 925 A. Additionally, FIG. 8 shows the results for the case where the distance d is set to 13 μm.

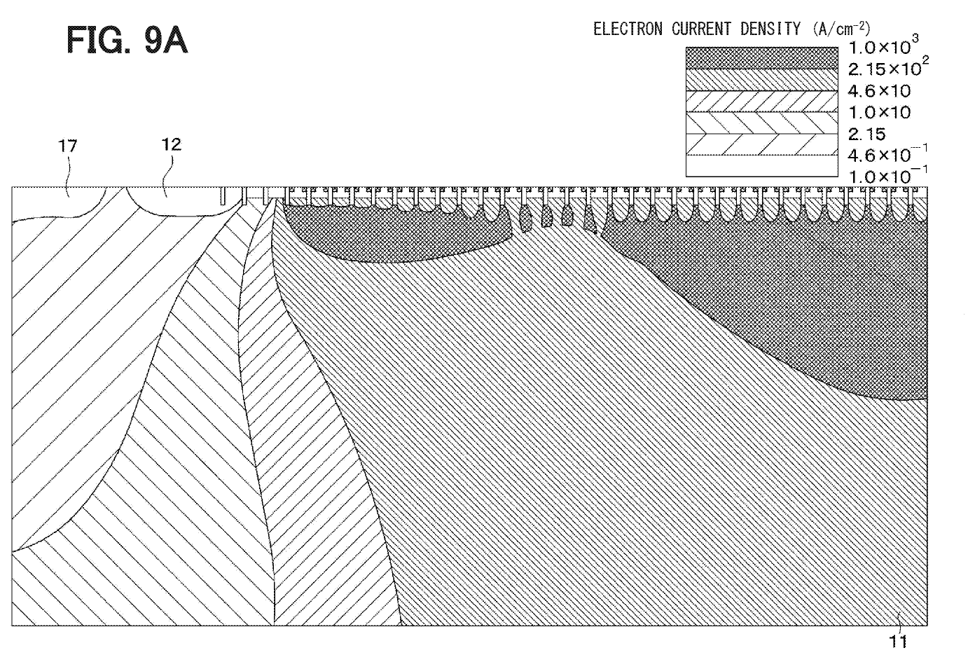

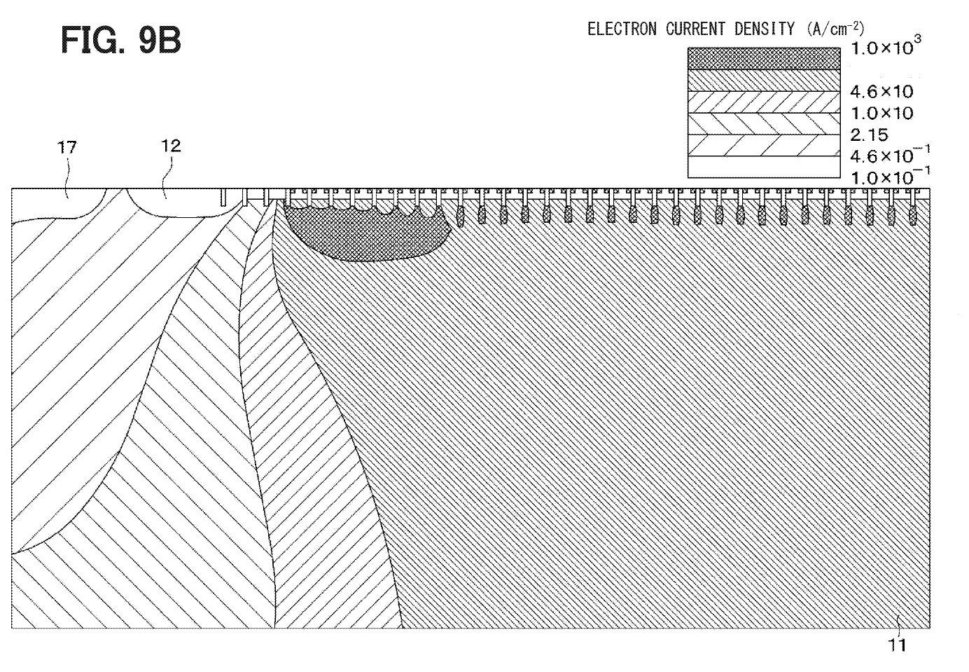

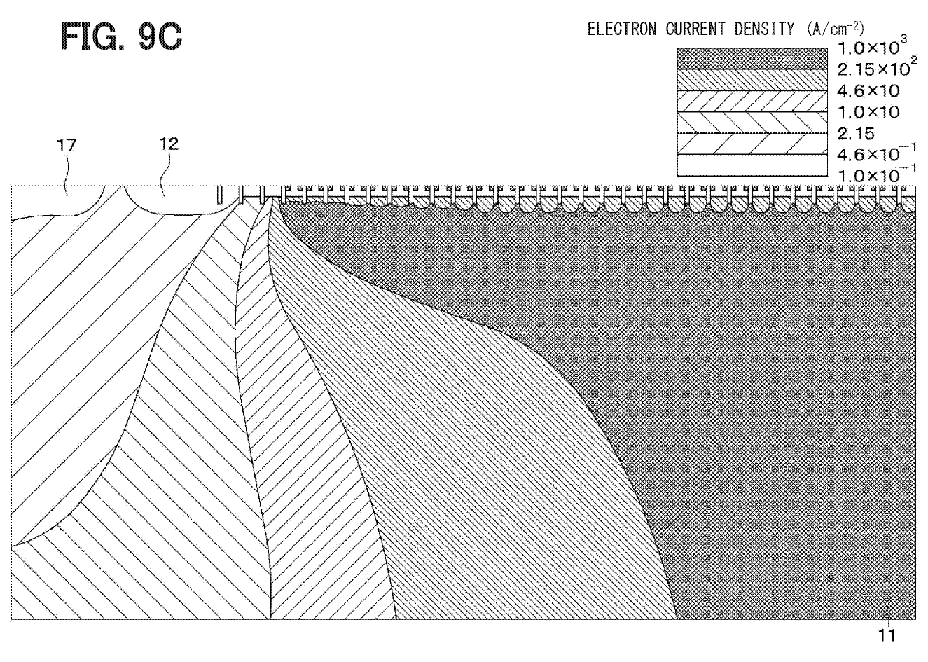

Furthermore, the present inventors conducted extensive studies on an electron current density for the model shown in FIG. 4 and obtained the results shown in FIGS. 9A to 9C. FIG. 9A is a diagram showing an electron current density at 25 °C. FIG. 9B is a diagram showing an electron current density at 90 °C. FIG. 9C is a diagram showing an electron current density at 150 °C. As shown in FIGS. 9A to 9C, it is confirmed that the electron current density, like the hole current density, hardly changes even when the temperature varies.

Then, the electron current and the hole current flowing in the main cell region Rm flow at a predetermined ratio according to the impurity concentrations and other factors of the drift layer 11, the base layer 12, and the emitter region 16. Therefore, in the present embodiment, the ratio between the main hole current MH and the sense hole current SH is previously determined through experiments or the like, and the ratio between the main hole current MH and the electron current in the main cell region Rm is also determined in advance. Then, when detecting the collector current IC flowing in the main cell region Rm, the main current is detected as follows, based on the previously determined ratio between the main hole current MH and the sense hole current SH, and the ratio between the main hole current MH and the electron current in the main cell region Rm. That is, the sense hole current SH is derived from the detection voltage Vs, and the main hole current MH is derived from the sense hole current SH. Then, by deriving the electron current from the main hole current MH, the main current flowing in the main cell region Rm is detected. In this case, since the hole current density and the electron current density are not affected by temperature as described above, there is no particular need for a circuit or the like to perform temperature compensation. In other words, according to the semiconductor device of the present embodiment, the main current can be detected with reduced influence from temperature, even without performing temperature compensation.

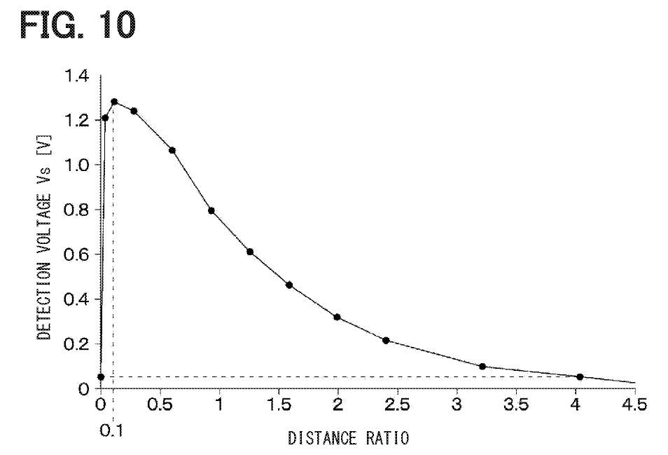

In the semiconductor device of the present embodiment, as described above, the sense hole current SH flows into the well layer 17 of the sense cell region Rs. In this case, if the distance d between the sense cell region Rs and the main cell region Rm is too large, the sense hole current SH may have difficulty flowing into the well layer 17, which could result in the detection voltage Vs becoming too small. Therefore, the present inventors defined the ratio of the distance d to the thickness of the semiconductor substrate 10 as a distance ratio, and conducted extensive studies on the relationship between the distance ratio and the detection voltage Vs, obtaining the results shown in FIG. 10. It should be noted that the detection voltage Vs in FIG. 10 is the result obtained when the resistance value of the detection resistor R is set to 1 Ω and the collector current IC is set to 925 A at 25 °C.

As shown in FIG. 10, it can be confirmed that when the distance ratio is 0.1 or less, the detection voltage Vs increases as the distance ratio increases. Furthermore, it can be confirmed that when the distance ratio is greater than 0.1, the detection voltage Vs decreases as the distance ratio increases, and when the distance ratio reaches 4 or more, the detection voltage Vs becomes lower than when the distance ratio is 0. Therefore, when the main cell region Rm and the sense cell region Rs are separated as in the present embodiment, it is preferable that the distance d between the main cell region Rm and the sense cell region Rs is adjusted so that the distance ratio is 4 or less.

It is assumed that the reason why the detection voltage Vs becomes smaller when the distance ratio is 0 (that is, when the well layer 17 and the base layer 12 are connected) is due to the following phenomenon. That is, when the detection voltage Vs is measured in a circuit configuration such as that shown in FIG. 3, if the well layer 17 and the base layer 12 are connected, the resistance between the well layer 17 and the base layer 12 tends to become smaller than the detection resistor R. Then, after the sense hole current SH flows into the well layer 17, a portion of the sense hole current SH exits through the base layer 12 of the main cell region Rm. Therefore, in the case where the distance ratio is 0, the sense hole current SH flowing through the detection resistor R decreases, so the detection voltage Vs is assumed to become smaller.

Therefore, if the detection voltage Vs becomes smaller than the desired value, it is preferable to appropriately adjust the magnitude of the detection voltage Vs by, for example, increasing the resistance value of the detection resistor R. However, if the resistance value of the detection resistor R is made too high, the potential difference between the sense electrode S and the emitter electrode E may become excessively large, potentially exceeding the breakdown voltage between the well layer 17 and the base layer 12. Therefore, when adjusting the resistance value of the detection resistor R, it is preferable to also take into account the breakdown voltage between the well layer 17 and the base layer 12. Specifically, it is preferable that the resistance value of the detection resistor R is set such that the potential of the sense electrode S becomes lower than a collector-emitter voltage of the main cell region Rm.

According to the embodiment described above, in the sense cell region Rs, the well layer 17 of P-type is formed on the drift layer 11, and when the main cell region Rm is in the ON state, a portion of the hole current flows into the sense cell region Rs. Then, when the detection resistor R is connected to the sense cell region Rs and the voltage across the detection resistor R is detected as the detection voltage Vs, the detection voltage Vs is not affected by temperature. Therefore, by detecting the main current flowing through the main cell region Rm based on the detection voltage Vs, it is possible to detect the main current in a state where the influence of temperature is reduced, without performing temperature correction.

In the present embodiment, the well layer 17 in the sense cell region Rs is spaced apart from the base layer 12 in the main cell region Rm. Therefore, it becomes more difficult for the holes that have flowed into the well layer 17 to escape from the well layer 17 to the base layer 12, making it easier to increase the detection voltage Vs.

In the present embodiment, by setting the distance ratio to 4 or less, the detection voltage Vs can be made larger than in the case where the well layer 17 is connected to the base layer 12.

### Second Embodiment

The following describes a second embodiment of the present disclosure. In the present embodiment, the well layer 17 is connected to the base layer 12, in contrast to the first embodiment described above. Other configurations are the same as those of the first embodiment, and therefore a description of the same configurations will be omitted.

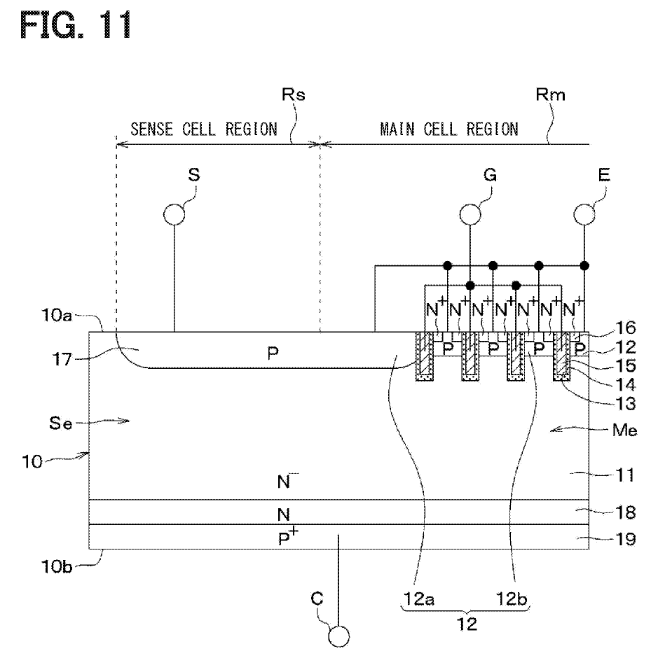

In the semiconductor device of the present embodiment, as shown in FIG. 11, the base layer 12 in the main cell region Rm and the well layer 17 in the sense cell region Rs are connected. In other words, the distance d between the main cell region Rm and the sense cell region Rs is set to zero, and the intermediate region Rt described in the first embodiment is not provided between the main cell region Rm and the sense cell region Rs. In the present embodiment, the well layer 17 is formed to have the same depth as the outer edge base layer 12a. It should be noted that, in such a semiconductor device, as explained in the first embodiment, the detection voltage Vs tends to become smaller. Therefore, in the present embodiment, it is preferable to appropriately adjust the resistance value of the detection resistor R.

According to the present embodiment, since the well layer 17 of P-type is formed on the drift layer 11 in the sense cell region Rs, the same effects as those of the first embodiment can be obtained.

In the present embodiment, the well layer 17 is connected to the base layer 12, and no intermediate region Rt is provided between the main cell region Rm and the sense cell region Rs. Therefore, it is possible to achieve miniaturization of the semiconductor device, and since voltage-resistant design for the intermediate region Rt is not required, the structure can be simplified.

### Modifications of Second Embodiment

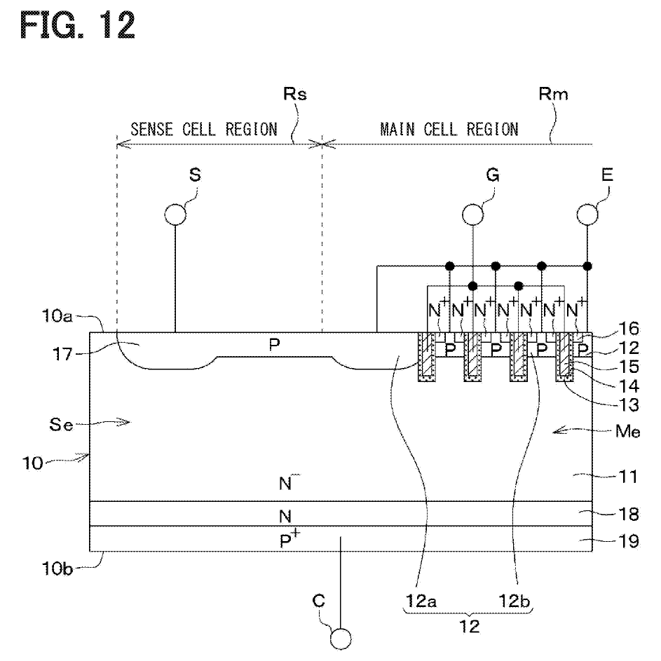

Modifications of the second embodiment will be described below. In the second embodiment described above, as shown in FIG. 12, the well layer 17 may have the same depth as the inner edge base layer 12b. That is, the well layer 17 does not necessarily have a uniform depth, and its depth may be adjusted according to the voltage resistance design. For example, in FIG. 12, a portion of the well layer 17 having the same depth as the inner edge base layer 12b is formed between a deeper portion of the well layer 17 and the base layer 12. Even with such a configuration, the same effects as those of the second embodiment can be obtained.

### Other Embodiments

Although the present disclosure has been described in accordance with the embodiments, it is understood that the present disclosure is not limited to such embodiments or structures. The present disclosure encompasses various modifications and variations within the scope of equivalents. In addition, while the various combinations and configurations are preferred, other combinations and configurations, including more, less, or only a single element, are also within the spirit and scope of the present disclosure.

For example, in each of the above-described embodiments, the example is described in which the first conductivity type is N-type and the second conductivity type is P-type. Alternatively, the first conductivity type may be P-type and the second conductivity type may be N-type.

Furthermore, in each of the above-described embodiments, the semiconductor device may be of a planar type in which the gate electrode layer 15 is disposed on the first surface 10a of the semiconductor substrate 10, rather than a trench-gate type.

Furthermore, in each of the above-described embodiments, the detection unit connected to the sense electrode S may be a current mirror circuit or the like, instead of the detection resistor R.

What is claimed is:

1. A semiconductor device comprising:
a semiconductor substrate having a main cell region in which a main element is disposed and a sense cell region in which a sense element is disposed, and including:
a drift layer of a first conductivity type disposed in the main cell region and the sense cell region,
a base layer of a second conductivity type disposed on the drift layer in the main cell region,
an emitter region of the first conductivity type disposed in a surface portion of the base layer and having a higher impurity concentration than the drift layer,
a gate insulating film disposed on a surface of the base layer between the emitter region and the drift layer,
a gate electrode layer disposed on the gate insulating film,
a collector layer of the second conductivity type disposed on a side of the drift layer opposite to the base layer, and
a well layer of the second conductivity type disposed on the drift layer in the sense cell region;
an emitter electrode electrically connected to the emitter region and the base layer;
a collector electrode electrically connected to the collector layer; and
a sense electrode electrically connected to the well layer, wherein
the main element includes the drift layer, the base layer, the emitter region, the gate insulating film, the gate electrode layer, and the collector layer,
the sense element includes the drift layer, the collector layer, and the well layer,
the sense element is configured to be connected to a detection unit, and a main current flowing through the main element is detected based on a detection result of the detection unit,
when a predetermined voltage is applied to the gate electrode layer, first carriers are supplied from the emitter electrode to the drift layer, second carriers are supplied from the collector electrode to the drift layer, and a portion of the second carriers supplied to the drift layer flows into the well layer, and
the well layer is spaced apart from the base layer in the main cell region, and the well layer has a distance ratio, which is a ratio of a distance between the well layer and the base layer to a thickness of the semiconductor substrate, of 4 or less.
